(19) United States
(12) Patent Application Publication
(10) Pub. No.: US 2025/0022940 A1
(43) Pub. Date: Jan. 16, 2025

(54) SEMICONDUCTOR DEVICES WITH IMPROVED GATE CONTROL

(71) Applicant: Taiwan Semiconductor Manufacturing Co., Ltd., Hsinchu (TW)

(72) Inventors: Che-Chun LU, Tainan (TW); Yi-Hsing CHU, Tainan City (TW); Chia-Yi TSENG, Tainan (TW)

(73) Assignee: Taiwan Semiconductor Manufacturing Co., Ltd., Hsinchu (TW)

(21) Appl. No.: 18/350,429

(22) Filed: Jul. 11, 2023

(51) Int. Cl. H01L 29/66; H01L 21/8238; H01L 27/092; H01L 29/06; H01L 29/08; H01L 29/423; H01L 29/775; H01L 29/78; H01L 29/786

(52) U.S. Cl. CPC H01L 29/66795; H01L 21/823807; H01L 21/823878; H01L 27/0924; H01L 29/0673; H01L 29/0847; H01L 29/42392; H01L 29/66439; H01L 29/6656; H01L 29/775; H01L 29/7851; H01L 29/78696

(57) ABSTRACT

The present disclosure describes forming a semiconductor structure having an isolation layer surrounding a portion of a gate structure. The semiconductor structure includes a channel structure on a substrate, a first isolation layer on the substrate and surrounding the channel structure, and a gate structure on the channel structure and the first isolation layer. The gate structure includes a first portion having a first width and a second portion having a second width less than the first width. The semiconductor structure further includes a second isolation layer on the first isolation layer and surrounding the first portion of the gate structure.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having an isolation layer surrounding a portion of a gate structure, in accordance with some embodiments.

FIGS. 2 and 3 illustrate cross-sectional views of a semiconductor device having an isolation layer surrounding a portion of a gate structure, in accordance with some embodiments.

FIG. 4 is a flow diagram of a method for forming an isolation layer surrounding a portion of a gate structure in a semiconductor device, in accordance with some embodiments.

FIGS. 5-15 illustrate isometric and cross-sectional views of a semiconductor device having an isolation layer surrounding a portion of a gate structure at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, fin structures of semiconductor devices can have sloped sidewalls. To improve gate control and reduce leakage current of the semiconductor devices, a bottom portion of the gate structure can have a larger width, which can be referred to as “gate footing.” However, during subsequent process of source/drain (S/D) epitaxial structures formation, the bottom portion of the gate structure can be etched through. As a result, metal gate extrusion defects and S/D epi pit defects can increase.

Various embodiments in the present disclosure provide example methods for forming an isolation layer surrounding a portion of a gate structure in a semiconductor device (e.g., a nanostructure transistor) and/or other semiconductor devices in an integrated circuit (IC). In some embodiments, a channel structure can be formed on a substrate and a first isolation layer can be formed on the substrate surrounding the channel structure. A gate structure can be formed on the channel structure and the first isolation layer. The gate structure can have a first portion having a first width and a second portion having a second width less than the first width. A second isolation layer can be formed on the first isolation layer to surround the first portion of the gate structure. In some embodiments, the second isolation layer can surround the gate footing portion of the gate structure to reduce the metal gate extrusion defects and S/D epi pit defects in subsequent processes. In some embodiments, the second isolation layer can improve the gate control and reduce the leakage current of the semiconductor device.

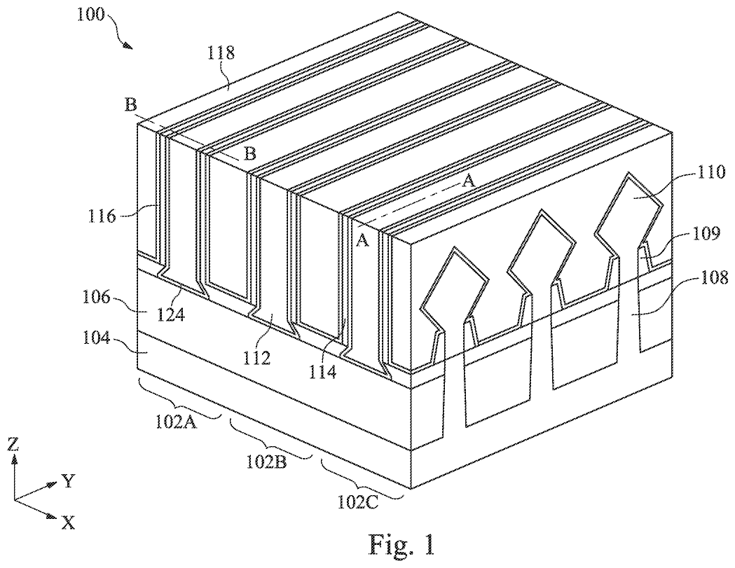

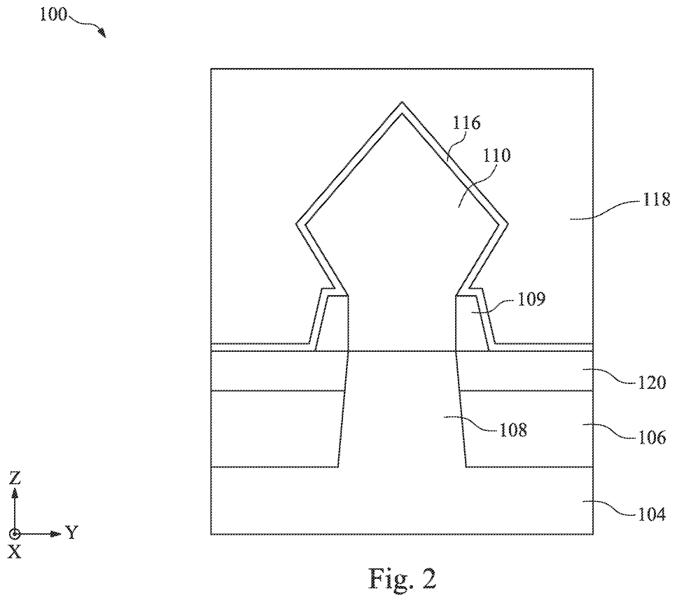

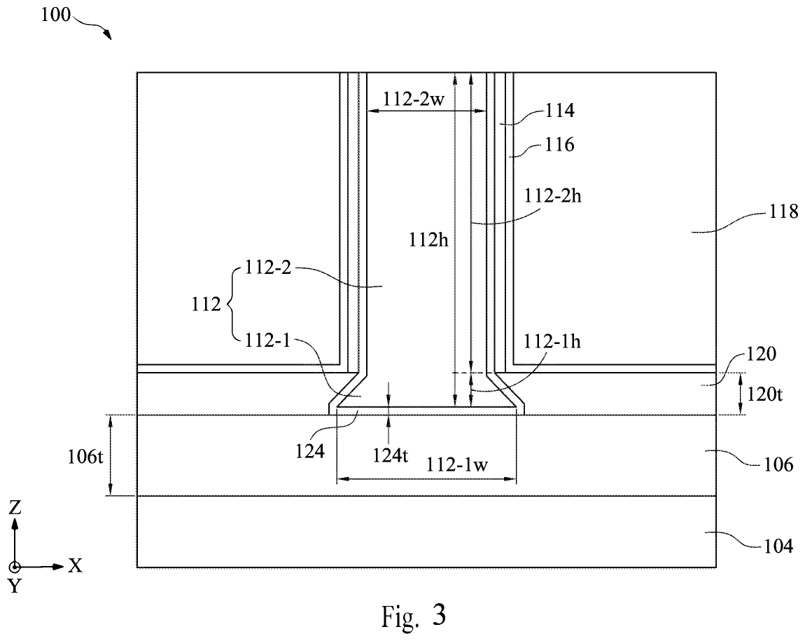

FIG. 1 illustrates an isometric view of a semiconductor device 100 having an isolation layer surrounding a portion of a gate structure, in accordance with some embodiments. FIG. 2 illustrates a partial cross-sectional view of semiconductor device 100 across line A-A shown in FIG. 1, in accordance with some embodiments. FIG. 3 illustrates a partial cross-sectional view of semiconductor device 100 across line B-B shown in FIG. 1, in accordance with some embodiments. In some embodiments, semiconductor device 100 can include transistors 102A-102C, as shown in FIG. 1. In some embodiments, transistors 102A-102C can be nanostructure transistors. The nanostructure transistors can include the finFETs, the gate-all-around field effect transistor (GAA FET), the nanosheet transistor, the nanowire transistor, the multi-bridge channel transistor, the nano-ribbon transistor, and other similar structured transistors. The nanostructure transistors can provide a channel in a fin structure or a stacked nanosheet/nanowire.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-3, semiconductor device 100 having transistors 102A-102C can be formed on a substrate 104 and can be isolated by first isolation layer 106 and second isolation layer 120. Each of transistors 102A-102C can include fin structures 108, fin sidewall spacers 109, gate dielectric layer 124, gate structures 112, gate spacers 114, S/D structures 110, etch stop layer (ESL) 116, and interlayer dielectric (ILD) layer 118. In some embodiments, fin structures 108 under gate structures 112 can extend above second isolation layer 120.

Referring to FIG. 1, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

Referring to FIGS. 1 and 2, fin structures 108 can be formed on patterned portions of substrate 104. Embodiments of the fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures.

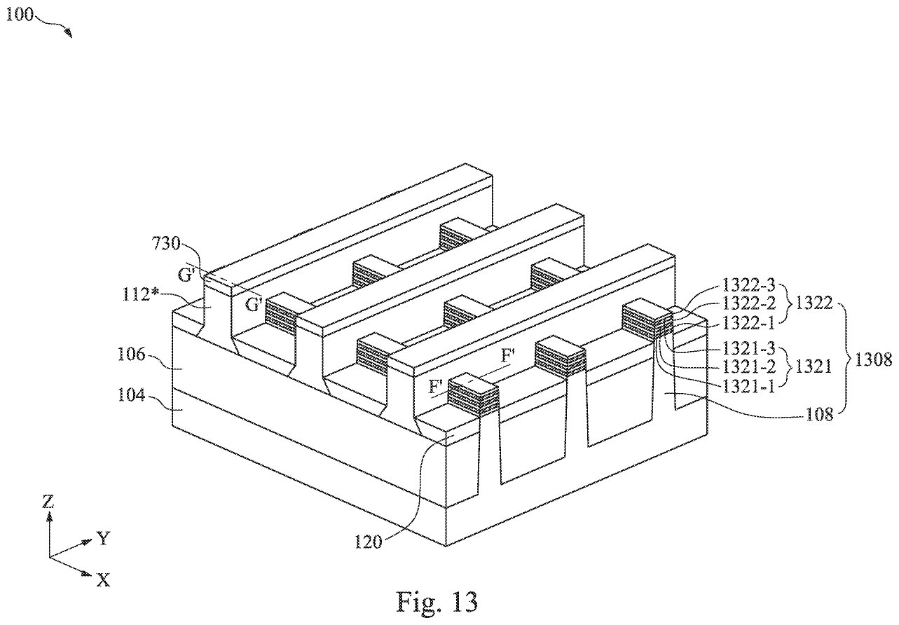

As shown in FIGS. 1 and 2, fin structures 108 can extend along an X-axis and through transistors 102A-102C. In some embodiments, fin structures 108 can be disposed on substrate 104. Fin structures 108 can act as a channel structure and form a channel region underlying gate structures 112 of transistors 102A-102C. In some embodiments, nanostructures, such as stacked nanosheets and nanowires, can be formed on fin structures 108 underlying gate structures 112. The nanostructures and fin structures 108 can act as channel structures of transistors 102A-102C, as shown in detail in FIGS. 13-15. In some embodiments, fin structures 108 can include semiconductor materials similar to or different from substrate 104. In some embodiments, fin structures 108 can include silicon. In some embodiments, fin structures 108 can include silicon germanium. The semiconductor materials of fin structures 108 can be undoped or can be in-situ doped during their formation process. In some embodiments, fin structures 108 under gate structures 112 can form channel regions of semiconductor device 100 and represent current carrying channel structures of semiconductor device 100.

First isolation layer 106 and second isolation layer 120 can provide electrical isolation between transistors 102A-102C and from neighboring transistors (not shown) on substrate 104 and/or neighboring active and passive elements (not shown) integrated with or deposited on substrate 104. In some embodiments, first isolation layer 106 and second isolation layer 120 can include the same dielectric material. In some embodiments, first isolation layer 106 and second isolation layer 120 can include different dielectric materials. In some embodiments, first isolation layer 106 and second isolation layer 120 can include silicon oxide, silicon nitride, silicon oxynitride, fluorine-doped silicate glass (FSG), a low-k dielectric material, and/or other suitable insulating materials. In some embodiments, second isolation layer 120 can include a dielectric material deposited using a deposition method suitable for flowable dielectric materials. For example, flowable silicon oxide can be deposited using flowable chemical vapor deposition (FCVD). In some embodiments, the dielectric material can be deposited by CVD, atomic layer deposition (ALD), and other suitable deposition processes. In some embodiments, gate structures 112 can be disposed above first isolation layer 106. Second isolation layer 120 can be disposed on first isolation layer 106 surrounding a bottom portion of gate structures 112. In some embodiments, first isolation layer 106 can have a thickness 106t along a Z-axis ranging from about 40 nm to about 60 nm. In some embodiments, second isolation layer 120 can have a thickness 120t ranging from about 10 nm to about 40 nm.

Referring to FIG. 2, gate dielectric layer 124 can be disposed on fin structures 108 and second isolation layer 120. In some embodiments, gate dielectric layer 124 can be multi-layered structures and can include an interfacial layer and a high-k dielectric layer. The term “high-k” can refer to a high dielectric constant. In the field of semiconductor device structures and manufacturing processes, high-k can refer to a dielectric constant that is greater than the dielectric constant of silicon oxide (e.g., greater than about 3.9). In some embodiments, the interfacial layer can include silicon oxide formed by a deposition process or an oxidation process. In some embodiments, the high-k dielectric layer can include hafnium oxide, zirconium oxide, or other suitable high-k dielectric materials. In some embodiments, gate dielectric layer 124 can have a thickness 124t along a Z-axis ranging from about 1 nm to about 5 nm.

In some embodiments, as shown in FIGS. 1 and 2, gate structures 112 can be disposed on gate dielectric layer 124 over fin structures 108 and second isolation layer 120. In some embodiments, gate structures 112 can include a first portion 112-1 surrounded by second isolation layer 120 and a second portion 112-2 above second isolation layer 120. In some embodiments, first portion 112-1 can be a bottom portion of gate structures 112 and second portion 112-2 can be a top portion of gate structures 112. In some embodiments, first portion 112-1 can be referred to as “gate footing” of gate structures 112 and can improve gate control of the current through fin structures 108. In some embodiments, first portion 112-1 can have a first width 112-1w ranging from about 15 nm to about 30 nm. In some embodiments, second portion 112-2 can have a second width 112-2w ranging from about 15 nm to about 20 nm. A ratio of first width 112-1w to second width 112-2w can range from about 1 to about 2. If first width 112-1w is less than about 15 nm or the ratio is less than about 1, gate control of the current in fin structures 108 by gate structures 112 may be decreased. If first width 112-1w is greater than about 30 nm or the ratio is greater than about 2, metal gate extrusion defects and epi pit defects in subsequent processes may increase.

In some embodiments, gate structures 112 can have a height 112h along a Z-axis ranging from about 100 nm to about 150 nm. In some embodiments, first portion 112-1 can have a height 112-1h along a Z-axis ranging from about 10 nm to about 40 nm. In some embodiments, second portion 112-2 can have a height 112-2h along a Z-axis ranging from about 90 nm to about 140 nm. In some embodiments, thickness 120t of second isolation layer 120 can be equal to or greater than first portion 112-1 of gate structures 112. A top surface of second isolation layer 120 can be above first portion 112-1 of gate structures 112. As a result, first portion 112-1 of gate structures 112 can be within second isolation layer 120. In some embodiments, a ratio of height 112-1h or thickness 120t to height 112h can range from about 5% to about 20%. If thickness 120t is less than about 10 nm or the ratio is less than about 5%, metal gate extrusion defects and epi pit defects may increase. If thickness 120t is greater than about 40 nm or the ratio is greater than about 20%, gate control of the current in fin structures 108 by gate structures 112 may be decreased.

In some embodiments, gate structures 112 can include one or more work function metal layers and a metal fill. The one or more work function metal layers can include work function metals to tune the threshold voltage (Vt) of transistors 102A-102C. In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1-3, gate spacers 114 can be disposed on sidewalls of gate structures 112, and fin sidewall spacers 109 can be disposed on sidewalls of fin structures 108. Gate spacers 114 and fin sidewall spacers 109 can include insulating materials, such as silicon oxide, silicon nitride, silicon oxynitride, silicon carbonitride, silicon oxycarbide, silicon oxycarbonitride, a low-k material, and a combination thereof. Gate spacers 114 and fin sidewall spacers 109 can include a single layer or a stack of insulating layers. Gate spacers 114 and fin sidewall spacers 109 can have a low-k material with a dielectric constant less than about 3.9 (e.g., about 3.5, about 3.0, or about 2.8).

S/D structures 110 can be disposed on fin structures 108 and on opposing sides of gate structures 112. S/D structures 110 can function as S/D regions of transistors 102A-102C. In some embodiments, S/D structures 110 can have any geometric shape, such as a polygon, an ellipsis, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium, and imparts a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions.

ESL 116 can be disposed on second isolation layer 120, S/D structures 110, sidewalls of gate spacers 114, and fin sidewall spacers 109. ESL 116 can be configured to protect second isolation layer 120, S/D structures 110, and gate structures 112 during the formation of S/D contact structures on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and second isolation layer 120. ILD layer 118 can include a dielectric material deposited using a deposition method suitable for flowable dielectric materials. For example, flowable silicon oxide can be deposited using FCVD. In some embodiments, the dielectric material can include silicon oxide.

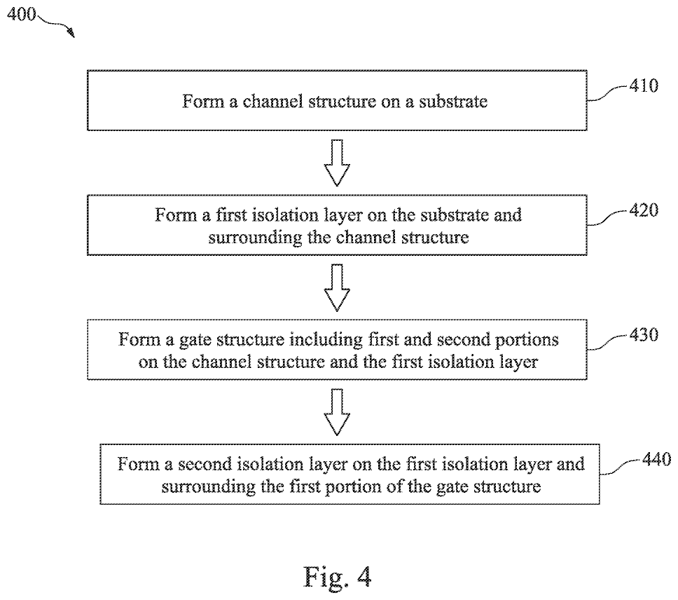

FIG. 4 is a flow diagram of a method 400 for fabricating semiconductor device 100 having an isolation layer surrounding a portion of a gate structure, in accordance with some embodiments. Method 400 may not be limited to nanostructure transistor devices and can be applicable to other devices that would benefit from the isolation layer surrounding a portion of the gate structure. Additional fabrication operations may be performed between various operations of method 400 and may be omitted merely for clarity and ease of description. Additional processes can be provided before, during, and/or after method 400; one or more of these additional processes are briefly described herein. Moreover, not all operations may be needed to perform the disclosure provided herein. Additionally, some of the operations may be performed simultaneously or in a different order than shown in FIG. 4. In some embodiments, one or more other operations may be performed in addition to or in place of the presently-described operations.

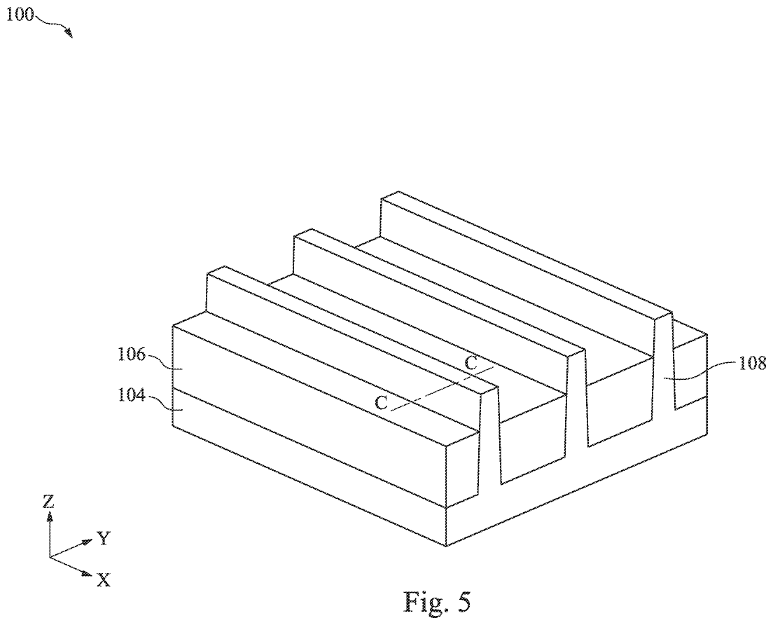

For illustrative purposes, the operations illustrated in FIG. 4 will be described with reference to the example fabrication process for fabricating semiconductor device 100 as illustrated in FIGS. 5-15. FIGS. 5-15 illustrate isometric and partial cross-sectional views of semiconductor device 100 having an isolation layer surrounding a portion of a gate structure at various stages of its fabrication, in accordance with some embodiments. Elements in FIGS. 5-15 with the same annotations as elements in FIGS. 1-3 are described above.

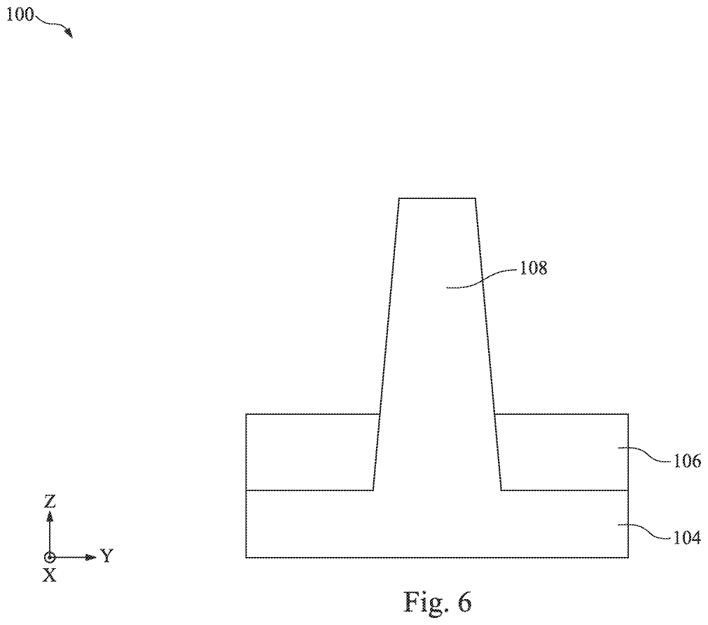

In referring to FIG. 4, method 400 begins with operation 410 and the process of forming a channel structure on a substrate. For example, as shown in FIGS. 5 and 6, fin structures 108 can be formed on substrate 104 and can act as channel structures in semiconductor device 100. FIG. 6 illustrates a partial cross-sectional view of semiconductor device 100 along line C-C as shown in FIG. 5, in accordance with some embodiments. In some embodiments, fin structures 108 can extend above first isolation layer 106. In some embodiments, fin structures 108 can include silicon. In some embodiments, fin structures 108 can include silicon germanium. The semiconductor materials of fin structures 108 can be undoped or can be in-situ doped during their formation process. In some embodiments, after the formation of fin structures 108, a protective layer (not shown) can be formed on fin structures 108. The protective layer can protect fin structures 108 during the etching processes in subsequent operations (e.g., formation of first isolation layer 106 and formation of gate structures 112).

Referring to FIG. 4, in operation 420, a first isolation layer can be formed on the substrate and surrounding the channel structure. For example, as shown in FIGS. 5 and 6, first isolation layer 106 can be formed on substrate 104 and surrounding fin structures 108. The formation of first isolation layer 106 can include depositing a layer of insulating material on substrate 104, annealing the layer of insulating material, chemical mechanical polishing (CMP) the annealed layer of insulating material, and etching back the polished structure to form the structure in FIGS. 5 and 6.

In some embodiments, the layer of insulating material can include silicon oxide, silicon nitride, silicon oxynitride, or a low-k dielectric material. In some embodiments, the layer of insulating material can be deposited using a CVD process, a high-density-plasma (HDP) CVD process, a sub-atmospheric CVD (SACVD) process, high aspect-ratio process (HARP), or other suitable deposition processes. In some embodiments, the layer of insulating material can be formed by depositing flowable silicon oxide using an FCVD process. The FCVD process can be followed by a wet anneal process. The wet anneal process can be followed by the CMP process to substantially coplanarize top surfaces of the layers of insulating material with top surfaces of fin structures 108. The CMP process can be followed by a dry etch process, a wet etch process, or a combination thereof to etch back the layer of insulating material to form the structure in FIGS. 5 and 6.

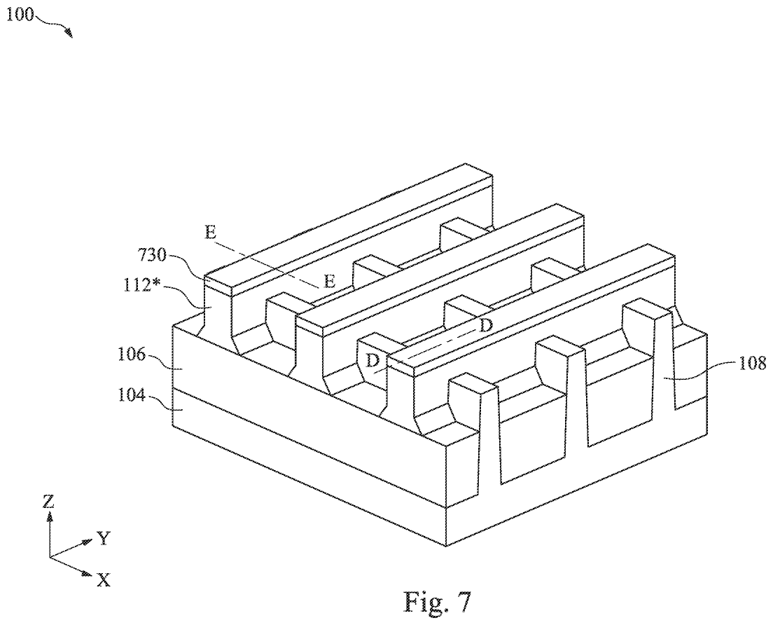

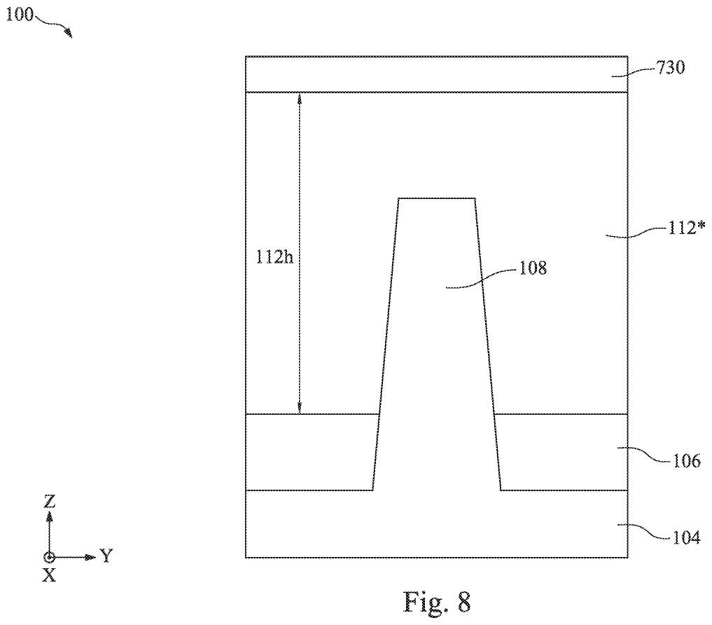

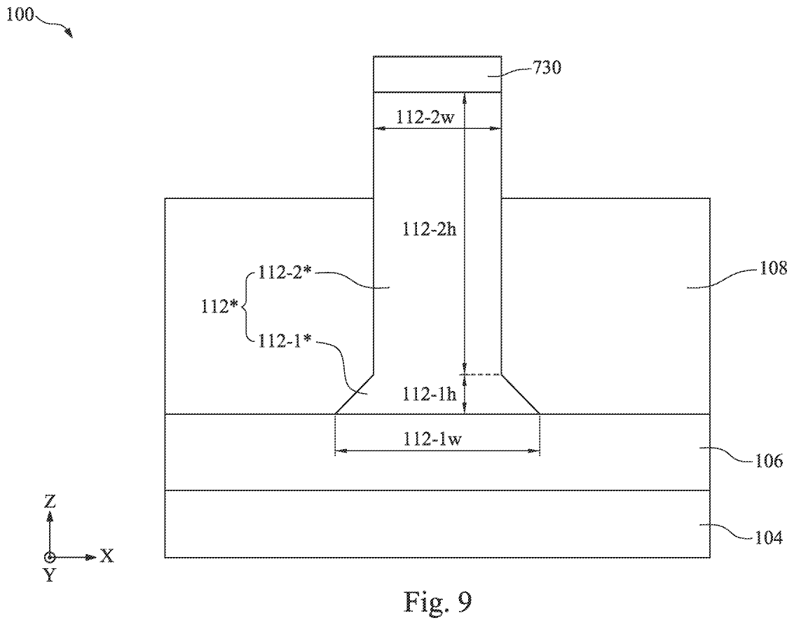

Referring to FIG. 4, in operation 430, a gate structure including first and second portions is formed on the channel structure and the first isolation layer. For example, as shown in FIGS. 7-9, gate structures 112* can be formed on fin structures 102 and first isolation layer 106. Gate structures 112* can include a first portion 112-1* and a second portion 112-2*. FIG. 8 illustrates a partial cross-sectional view of semiconductor device 100 along line D-D as shown in FIG. 7, in accordance with some embodiments. FIG. 9 illustrates a partial cross-sectional view of semiconductor device 100 along line E-E as shown in FIG. 7, in accordance with some embodiments. In some embodiments, gate structures 112* can include polysilicon and can be replaced in a subsequent gate replacement process to form gate structures 112 of transistors 102A-102C, as shown in FIGS. 1 and 2.

In some embodiments, the formation of gate structures 112* can include blanket depositing a layer of polysilicon material on fin structures 108 and first isolation layer 106 and etching the layer of polysilicon material through a patterned hard mask layer 730 formed on the layer of polysilicon material. The blanket deposition of the layer of polysilicon material can include CVD, physical vapor deposition (PVD), or other suitable deposition processes. In some embodiments, the polysilicon material can be undoped and hard mask layer 730 can include an oxide layer and/or a nitride layer. Hard mask layer 730 can protect gate structures 112* during subsequent processing operations (e.g., formation of gate spacers 114, S/D structures 110, and/or ILD layer 118).

In some embodiments, etching of the deposited layer of polysilicon material can include a dry etch, a wet etching, or a combination thereof. In some embodiments, etching of the deposited layer of polysilicon material can include multiple etching steps to form first portion 112-1* and second portion 112-2* of gate structures 112*. In some embodiments, first portion 112-1* can be a bottom portion of gate structures 112* and second portion 112-2* can be a top portion of gate structures 112*. In some embodiments, first portion 112-1* can be referred to as “gate footing” of gate structures 112* and can improve gate control of the current through fin structures 108. In some embodiments, first portion 112-1* can have a first width 112-1w ranging from about 15 nm to about 30 nm. In some embodiments, second portion 112-2* can have a second width 112-2w ranging from about 15 nm to about 20 nm. A ratio of first width 112-1w to second width 112-2w can range from about 1 to about 2. If first width 112-1w is less than about 15 nm or the ratio is less than about 1, gate control of the current in fin structures 108 by subsequently-formed gate structures 112 may be decreased. If first width 112-1w is greater than about 30 nm or the ratio is greater than about 2, metal gate extrusion defects and epi pit defects may increase.

In some embodiments, gate structures 112* can have a height 112h along a Z-axis ranging from about 100 nm to about 150 nm. In some embodiments, first portion 112-1* can have a height 112-1h along a Z-axis ranging from about 10 nm to about 40 nm. In some embodiments, second portion 112-2* can have a height 112-2h along a Z-axis ranging from about 90 nm to about 140 nm. In some embodiments, a ratio of height 112-1h to height 112h can range from about 5% to about 20%. If height 112-1h is less than about 10 nm or the ratio is less than about 5%, gate control of the current in fin structures 108 by subsequently-formed gate structures 112 may be decreased. If height 112-1h is greater than about 40 nm or the ratio is greater than about 20%, metal gate extrusion defects and epi pit defects may increase.

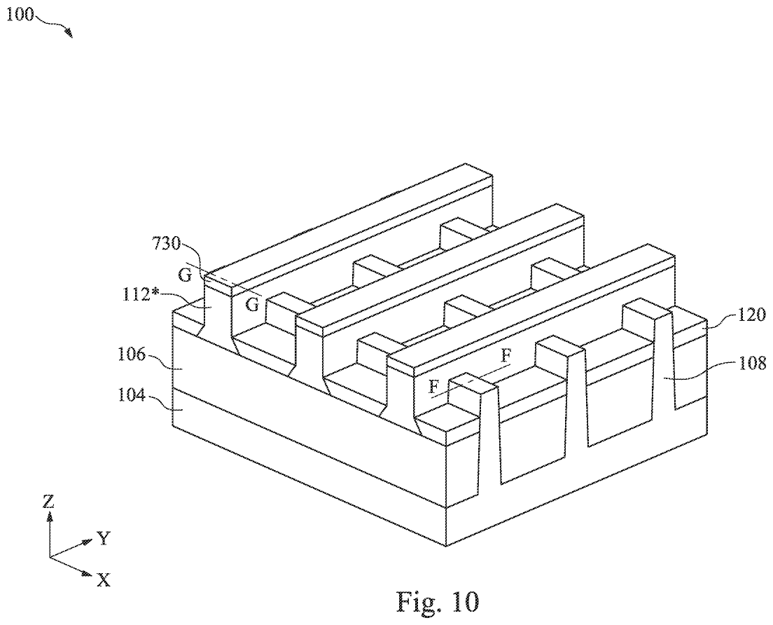

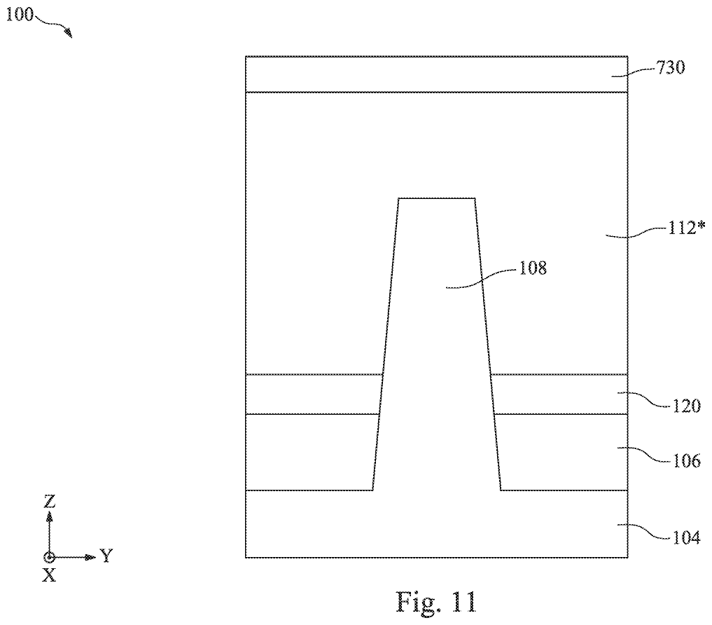

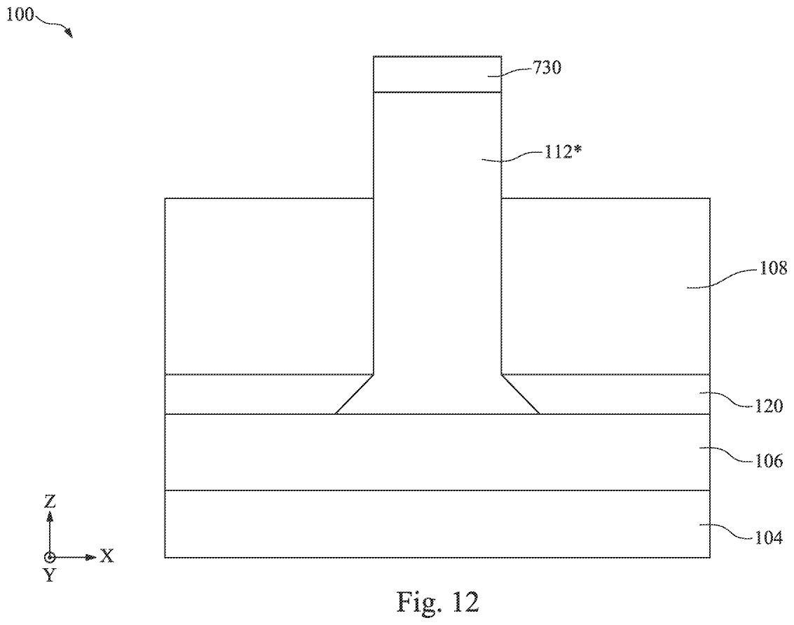

Referring to FIG. 4, in operation 440, a second isolation layer is formed on the first isolation layer surrounding the first portion of the gate structure. For example, as shown in FIGS. 10-12, second isolation layer 120 can be formed on first isolation layer surrounding first portion 112-1* of gate structures 112*. FIG. 11 illustrates a partial cross-sectional view of semiconductor device 100 along line F-F as shown in FIG. 10, in accordance with some embodiments. FIG. 12 illustrates a partial cross-sectional view of semiconductor device 100 along line G-G as shown in FIG. 10, in accordance with some embodiments. In some embodiments, second isolation layer 120 can include a dielectric material deposited using a deposition method suitable for flowable dielectric materials. For example, flowable silicon oxide can be deposited using FCVD. In some embodiments, the dielectric material can be deposited by CVD, ALD, and other suitable deposition processes. In some embodiments, second isolation layer 120 can include silicon oxide, silicon oxynitride, silicon carbonitride, silicon oxycarbide, silicon oxycarbonitride, and a combination thereof deposited by an FCVD process.

In some embodiments, the FCVD process can include deposition of a flowable dielectric material, a curing process, and an anneal process. In some embodiments, the flowable dielectric material can be deposited on surfaces of semiconductor device 100 to fill spaces between fin structures 108 and gate structures 112*. In some embodiments, the curing process can include an ozone pre-soak process and an ultra-violet (UV) curing process. During the ozone pre-soak process, the flowable dielectric material can be treated in an ozone environment to form an oxide-like crust layer on the surface of the flowable dielectric material. During the UV curing process, the flowable dielectric material can be treated under UV light environment to out gas and harden the flowable dielectric material. In some embodiments, the anneal process can include a wet anneal process, a dry anneal process, or a combination thereof. The anneal process can include annealing the cured flowable dielectric material at a temperature in a range from about 200° C. to about 700° C. for a period in a range from about 30 min to about 120 min.

In some embodiments, the FCVD process can be followed by a CMP process to substantially coplanarize top surfaces of the annealed flowable dielectric material with top surfaces of hard mask layer 730. The CMP process can be followed by a dry etch process, a wet etch process, or a combination thereof to etch back the flowable dielectric material to form second isolation layer 120 as shown in FIGS. 10-12.

In some embodiments, second isolation layer 120 can have a thickness 120t ranging from about 10 nm to about 40 nm. In some embodiments, thickness 120t of second isolation layer 120 can be equal to or greater than first portion 112-1* of gate structures 112*. A top surface of second isolation layer 120 can be above first portion 112-1* of gate structures 112*. As a result, second isolation layer 120 can surround first portion 112-1* of gate structures 112* and first portion 112-1* can be within second isolation layer 120. Subsequently-formed S/D structures 110 (shown in FIG. 1) can be above second isolation layer 120 and etching of first portion 112-1* during formation of S/D structures 110 can be avoided. Accordingly, epi pit defects and metal gate extrusion defects can be decreased. In some embodiments, a ratio of thickness 120t to height 112h can range from about 5% to about 20%. If thickness 120t is less than about 10 nm or the ratio is less than about 5%, metal gate extrusion defects and epi pit defects may increase. If thickness 120t is greater than about 40 nm or the ratio is greater than about 20%, gate control of the current in fin structures 108 by gate structures 112 may be decreased.

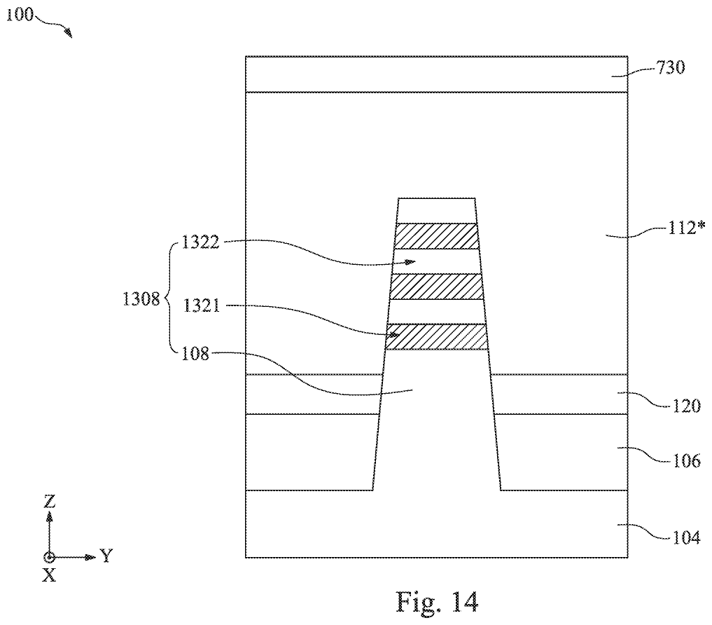

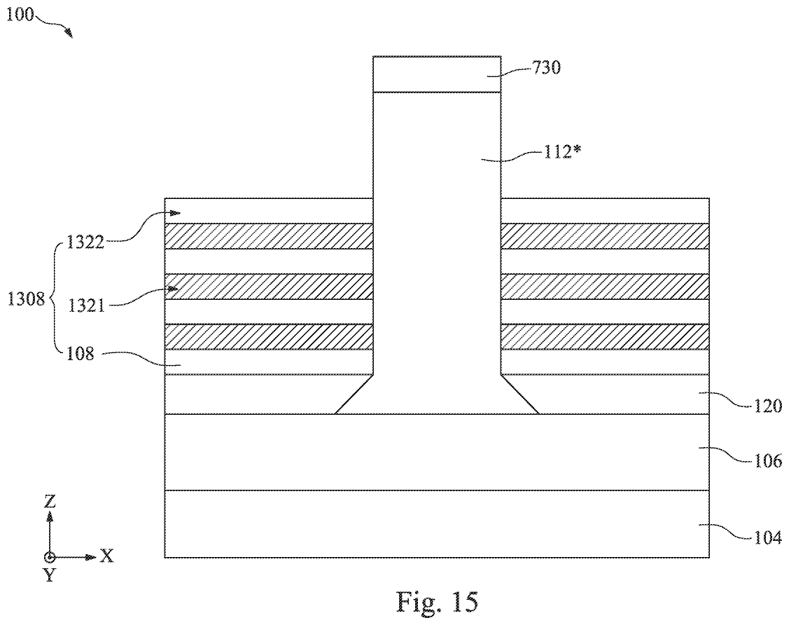

In some embodiments, as shown in FIGS. 13-15, channel structures 1308 can be formed on substrate 104 and gate structures 112* can be formed on channel structures 1308. FIG. 14 illustrates a partial cross-sectional view of semiconductor device 100 along line F′-F′ as shown in FIG. 13, in accordance with some embodiments. FIG. 15 illustrates a partial cross-sectional view of semiconductor device 100 along line G′-G′ as shown in FIG. 13, in accordance with some embodiments. Channel structures 1308 can include fin structures 108, a first set of semiconductor layers 1321-1, 1321-2, and 1321-3 (collectively referred to as “semiconductor layers 1321”), and a second set of semiconductor layers 1322-1, 1322-2, and 1322-3 (collectively referred to as “semiconductor layers 1322”). First and second sets of semiconductor layers 1321 and 1322 can be stacked in an alternate configuration. Second isolation layer can surround first portion 112-1* of gate structures 112* and fin structures 108. A top surface of fin structures 108 can be above a top surface of second isolation layer 120.

In some embodiments, first and second sets of semiconductor layers 1321 and 1322 can be epitaxially grown on substrate 104 and subsequently etched to form channel structures 1308. In some embodiments, first set of semiconductor layers 1321 can include a semiconductor material different from substrate 104. Second set of semiconductor layers 1322 can include a semiconductor material the same as substrate 104. In some embodiments, substrate 104 and second set of semiconductor layers 1322 can include silicon. First set of semiconductor layers 1321 can include silicon germanium. In some embodiments, a germanium concentration in the silicon germanium can range from about 10% to about 50% to increase etch selectivity between first and second sets of semiconductor layers 1321 and 1322. In some embodiments, first set of semiconductor layers 1321 can have a thickness along a Z-axis ranging from about 3 nm to about 10 nm. Second set of semiconductor layers 1322 can have a thickness along a Z-axis ranging from about 5 nm to about 15 nm.

The formation of second isolation layer 120 can be can be followed by formation of gate spacers 114 on sidewall surfaces of gate structures 112* and top surfaces of second isolation layer 120, formation of S/D structures 110 on fin structures 108 and above second isolation layer 120, removal of gate structures 112*, removal of semiconductor layers 1321, formation of gate dielectric layer 124 on fin structures 108, semiconductor layers 1322, and second isolation layer 120, formation of gate structures 112 on gate dielectric layer 124, and formation of ESL 116 and ILD layer 118, which are not described in detail for clarity. After these operations, semiconductor device 100 having second isolation layer 120 surrounding first portion 112-1 of gate structures 112 can be fabricated as in FIGS. 1-2.

Various embodiments in the present disclosure provide example methods for forming second isolation layer 120 surrounding first portion 112-1 of gate structures 112 in semiconductor device 100. In some embodiments, fin structures 108 can be formed on substrate 104 and first isolation layer 106 can be formed on substrate 104 surrounding fin structures 108. Gate structures 112* can be formed on fin structures 108 and first isolation layer 106. Gate structures 112* can have first portion 112-1* having first width 112-1w and second portion 112-2* having a second width 112-2w less than first width 112-1w. Second isolation layer 120 can be formed on first isolation layer 106 to surround first portion 112*-1 of gate structures 112*. In some embodiments, second isolation layer 120 can surround gate footing portion of gate structures 112* to reduce the metal gate extrusion defects and S/D epi pit defects in subsequent processes. In some embodiments, second isolation layer 120 can improve the gate control and reduce the leakage current of the semiconductor device.

A semiconductor structure includes a channel structure on a substrate, a first isolation layer on the substrate and surrounding the channel structure, and a gate structure on the channel structure and the first isolation layer. The gate structure includes a first portion having a first width and a second portion having a second width less than the first width. The semiconductor structure further includes a second isolation layer on the first isolation layer and surrounding the first portion of the gate structure.

A semiconductor structure includes first and second channel structures on a substrate, a first isolation layer on the substrate and between the first and second channel structures, and a gate structure on the first isolation layer and over the first and second channel structures. The gate structure includes a first portion on the isolation layer and a second portion above the first portion. The semiconductor structure further includes a second isolation layer on the first isolation layer and between the first and second channel structures. The first portion of the gate structure is within the second isolation layer.

A method includes forming a channel structure on a substrate, forming a first isolation layer on the substrate and surrounding the channel structure, and forming a gate structure on the channel structure and the first isolation layer. The gate structure includes a first portion having a first width and a second portion having a second width less than the first width. The method further includes forming a second isolation layer on the first isolation layer. The second isolation layer surrounds the first portion of the gate structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

1. A semiconductor structure, comprising:
a channel structure on a substrate;
a first isolation layer on the substrate and surrounding the channel structure;
a gate structure on the channel structure and the first isolation layer, wherein the gate structure comprises a first portion having a first width and a second portion having a second width less than the first width; and
a second isolation layer on the first isolation layer and surrounding the first portion of the gate structure.

2. The semiconductor structure of claim 1, further comprising a gate dielectric layer between the gate structure and the second isolation layer.

3. The semiconductor structure of claim 1, further comprising a source/drain structure on the channel structure and above the second isolation layer.

4. The semiconductor structure of claim 1, wherein a top surface of the second isolation layer is above the first portion of the gate structure.

5. The semiconductor structure of claim 1, wherein a ratio of the first width of the first portion to the second width of the second portion ranges from about 1 to about 2.

6. The semiconductor structure of claim 1, wherein a ratio of a height of the first portion of the gate structure to a height of the gate structure ranges from about 5% to about 20%.

7. The semiconductor structure of claim 1, further comprising a gate spacer on a top surface of the second isolation layer and sidewall surfaces of the gate structure.

8. A semiconductor structure, comprising:
first and second channel structures on a substrate;
a first isolation layer on the substrate and between the first and second channel structures;
a gate structure on the first isolation layer and over the first and second channel structures, wherein the gate structure comprises a first portion on the first isolation layer and a second portion above the first portion; and
a second isolation layer on the first isolation layer and between the first and second channel structures, wherein the first portion of the gate structure is within the second isolation layer.

9. The semiconductor structure of claim 8, further comprising a gate dielectric layer between the gate structure and the second isolation layer.

10. The semiconductor structure of claim 8, further comprising a first source/drain structure on the first channel structure and a second source/drain structure on the second channel structure, wherein the first and second source/drain structures are above the second isolation layer.

11. The semiconductor structure of claim 8, wherein a top surface of the second isolation layer is above the first portion of the gate structure.

12. The semiconductor structure of claim 8, wherein the first portion of the gate structure has a first width and the second portion of the gate structure has a second width less than the first width.

13. The semiconductor structure of claim 12, wherein a ratio of the first width to the second width ranges from about 1 to about 2.

14. The semiconductor structure of claim 8, wherein a ratio of a thickness of the second isolation layer to a height of the gate structure ranges from about 5% to about 20%.

15. The semiconductor structure of claim 8, further comprising a gate spacer on a top surface of the second isolation layer and sidewall surfaces of the gate structure.

16. A method, comprising:
forming a channel structure on a substrate;
forming a first isolation layer on the substrate and surrounding the channel structure;
forming a gate structure on the channel structure and the first isolation layer, wherein the gate structure comprises a first portion having a first width and a second portion having a second width less than the first width; and
forming a second isolation layer on the first isolation layer, wherein the second isolation layer surrounds the first portion of the gate structure.

17. The method of claim 16, further comprising forming a gate dielectric layer on the channel structure and the first isolation layer.

18. The method of claim 16, further comprising forming a source/drain structure on the channel structure and above the second isolation layer.

19. The method of claim 16, wherein forming the second isolation layer comprises depositing a dielectric material on the first isolation layer using a flowable chemical vapor deposition method.

20. The method of claim 16, further comprising forming a gate spacer on a top surface of the second isolation layer and sidewall surfaces of the gate structure.
